(19) United States
(12) Patent Application Publication
(10) Pub. No.: US 2025/0137576 A1
(43) Pub. Date: May 1, 2025

(54) Vibration Insulating Structure And Method For Manufacturing Vibration Insulating Structure

(71) Applicant: SEIKO EPSON CORPORATION, Tokyo (JP)

(72) Inventor: Yoshihiro KOBAYASHI, Komagane (JP)

(21) Appl. No.: 18/926,391

(22) Filed: Oct. 25, 2024

(30) Foreign Application Priority Data
Oct. 26, 2023 (JP) 2023-183796

(51) Int. Cl. F16M 11/22; F16F 7/108; G06F 30/17

(52) U.S. Cl. CPC F16M 11/22; F16F 7/108; G06F 30/17; F16F 2222/08; F16F 2226/04; F16F 2230/00

(57) ABSTRACT

A vibration insulating structure is fixed to a vibration source and on which a measurement apparatus is placed, the vibration insulating structure including: a first vibration insulating structure fixed to the vibration source and a second vibration insulating structure provided on top of the first vibration insulating structure, in which the first vibration insulating structure includes a first mass body and a first vibration insulating member supporting the first mass body, the second vibration insulating structure includes a second mass body and a second vibration insulating member supporting the second mass body, the measurement apparatus is placed on the second mass body, and a second structure ratio of the second vibration insulating structure is larger than a first structure ratio of the first vibration insulating structure.

The present application is based on, and claims priority from JP Application Serial Number 2023-183796, filed Oct. 26, 2023, the disclosure of which is hereby incorporated by reference herein in its entirety.

### BACKGROUND

### 1. Technical Field

The present disclosure relates to a vibration insulating structure for an inertial measurement unit and a method for manufacturing the vibration insulating structure.

### 2. Related Art

There is known an inertial measurement unit (IMU) which includes a plurality of sensors such as an angular velocity sensor and an acceleration sensor and is used for measurement of a displacement of a building, a structure, or the like. With an existing structure of an inertial measurement unit, accurate measurement data cannot be detected when external vibration not from a detection target propagates to the sensors. Hence, providing an inertial measurement apparatus with a vibration insulating structure has been proposed.

For example, JP-A-2022-50915 discloses an inertial measurement unit having a vibration insulating structure. This inertial measurement apparatus has a vibration insulating structure holding a sensor unit including an inertial senor, and the vibration insulating structure is configured having a stack of a first substrate and a second substrate. Vibration insulating members such as gel bushings are provided between the first substrate and the second substrate to prevent external vibration from propagating to the sensor unit.

However, the inertial measurement unit in JP-A-2022-50915 has room for improvement. Specifically, a description about optimizing the vibration insulating structure considering vibration insulating characteristics including a resonant frequency and an amplitude amplification factor is not found in JP-A-2022-50915, which may mean insufficient vibration insulating performance.

Thus, there is a demand for a vibration insulating structure having desired vibration insulating characteristics and a method for manufacturing the same.

### SUMMARY

A vibration insulating structure according to an aspect of the present disclosure is a vibration insulating structure which is fixed to a vibration source and on which a measurement apparatus is placed, the vibration insulating structure including: a first vibration insulating structure fixed to the vibration source and a second vibration insulating structure provided on top of the first vibration insulating structure, in which the first vibration insulating structure includes a first mass body and a first vibration insulating member supporting the first mass body, the second vibration insulating structure includes a second mass body and a second vibration insulating member supporting the second mass body, the measurement apparatus is placed on the second mass body, and a second structure ratio of the second vibration insulating structure is larger than a first structure ratio of the first vibration insulating structure.

A method for manufacturing a vibration insulating structure is a method for manufacturing a vibration insulating structure having a first vibration insulating structure fixed to a vibration source and a second vibration insulating structure provided on top of the first vibration insulating structure, the first vibration insulating structure including a first mass body and a first vibration insulating member, the second vibration insulating structure including a second mass body on which a measurement apparatus is placed and a second vibration insulating member, the method including: obtaining a unit parameter for a vibration insulating member to use from a database of the unit parameter; generating a reference parameter based on a desired resonant frequency and a desired amplitude amplification factor; based on the reference parameter, defining three points on a coordinate system of a correlation between a resonant frequency and an amplitude amplification factor; based on the three points on the coordinate system, calculating an approximate straight line of a given structure ratio Rr; dividing the approximate straight line based on a division ratio and calculating a quantity of the second mass body and a quantity of the second vibration insulating member in the second vibration insulating structure; and outputting calculation results obtained by the calculating.

### BRIEF DESCRIPTION OF THE DRAWINGS

FIG. 1 is a plan view of a vibration insulating structure according to Embodiment 1.

FIG. 2 is a side view of the vibration insulating structure.

FIG. 3 is a sectional view of the vibration insulating member taken along a section III-III in FIG. 1.

FIG. 4 is a schematic view of a modeled vibration insulating structure.

FIG. 5 is a vibration model used in designing a vibration insulating structure.

FIG. 6 is a flowchart showing how unit parameters are obtained.

FIG. 7 is an overview diagram of a unit-parameter measurement apparatus.

FIG. 8 is a graph showing an example of gain-frequency characteristics.

FIG. 9 is a flowchart showing how a vibration insulating structure is designed.

FIG. 10 is a graph showing an example correlation of a given structure ratio Rr and an amplitude amplification factor.

FIG. 11 is a graph showing an example correlation of a given structure ratio Rr and a resonant frequency.

FIG. 12 is a graph showing an example correlation of a resonant frequency and an amplitude amplification factor using the structure ratio Rr as a parameter.

FIG. 13 is a plan view of a vibration insulating structure according to Embodiment 2.

FIG. 14 is a side view of the vibration insulating structure.

FIG. 15 is a diagram of a vibration model used in designing a double-layer vibration insulating structure.

FIG. 16 is a flowchart showing how a double-layer vibration insulating structure is designed.

FIG. 17 is a graph showing an example correlation of a given structure ratio Rr and an amplitude amplification factor with respect to a vibration insulating structure 0 and a vibration insulating structure 2.

FIG. 18 is a graph showing an example correlation of a given structure ratio Rr and a resonant frequency with respect to the vibration insulating structure 0 and the vibration insulating structure 2.

FIG. 19 is a graph showing an example correlation of a resonant frequency and an amplitude amplification factor using the structure ratio Rr of the vibration insulating structure 2 as a parameter.

FIG. 20 is a graph showing a close-up of an area around an approximate straight line in FIG. 19.

FIG. 21 is a functional block diagram of a measurement apparatus including a vibration insulating structure.

FIG. 22 is a graph showing a correlation between a bandwidth of a measurement apparatus and the gain-frequency characteristics of a vibration insulating structure.

FIG. 23 is a diagram showing an example mode of installment of a vibration insulating structure.

### DESCRIPTION OF EMBODIMENTS

### Embodiment 1

### ***Overview of a Vibration Insulating Structure***

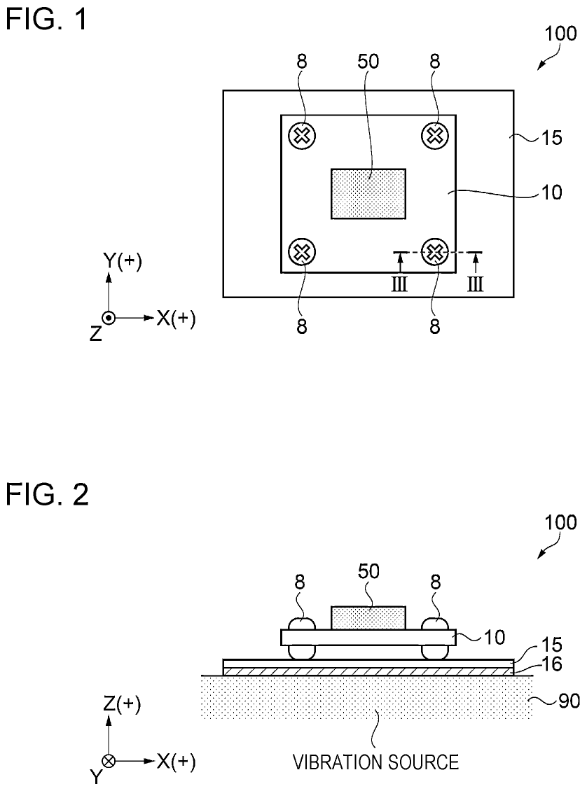

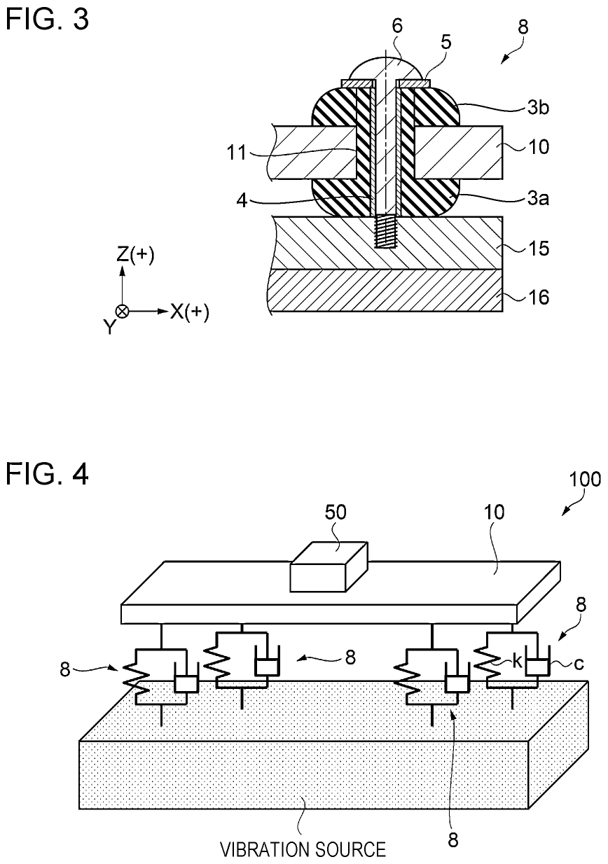

FIG. 1 is a plan view of a vibration insulating structure according to the present embodiment. FIG. 2 is a side view of the vibration insulating structure. FIG. 3 is a sectional view of the vibration insulating member along a section III-III in FIG. 1.

An vibration insulating structure 100 of the present embodiment is a base having a vibration insulating function on which to place a measurement apparatus 50, which is an inertial measurement unit (IMU) including a plurality of sensors such as an angular velocity sensor and an acceleration sensor and used for measurement of a displacement of a building, a structure, or the like. Note that the measurement apparatus 50 is not limited to an IMU and may be, for example, an inertial navigation system (INS) or may be an acceleration sensor, a displacement meter, a gyroscope sensor, an optical sensor, or an image measurement apparatus. In other words, the measurement apparatus 50 is any one of an inertial measurement unit, an inertial navigation system, an acceleration sensor, a displacement meter, a gyroscope sensor, an optical sensor, and an image measurement apparatus.

As shown in FIGS. 1 and 2, the measurement apparatus 50 is substantially cuboid and is placed on a rectangular substrate 10. The substrate 10 is attached to a base substrate 15 through vibration insulating members 8 provided at four corners of the substrate 10. The base substrate 15 is a metallic substrate slightly larger than the substrate 10, and a plate-shaped magnet 16 being substantially the same size as the base substrate 15 is attached to the lower surface of the base substrate 15. The magnet 16 is pulled and fixed onto a magnetic metal portion of a vibration source. Note that the magnet 16 is not limited to a plate-shaped magnet and may be a coin-shaped magnet, in which case it is preferable that the coin-shaped magnet be disposed at a plurality of locations on the base substrate 15, including its four corners.

Note that the drawings depict an X-axis, a Y-axis, and a Z-axis as three axes orthogonal to one another. In the present embodiment, a direction in which longer sides of the substrate 10 substantially rectangular in a plan view extend is an +X-direction, a direction in which its shorter sides extend is a +Y-direction, and a direction of the height of the vibration insulating structure 100 is a +Z-direction. The +X-direction and a −X-direction are together referred to as an X-axis direction. The same applies to the Y-axis and the Z-axis. The +Z-direction is also referred to as up; a −Z-direction, down.

As shown in FIG. 2, the vibration insulating structure 100 is configured such that the substrate 10 is provided on top of the base substrate 15. In a preferred example, the substrate 10 is a flat substrate made of aluminum. Note that the material for the substrate 10 is not limited to aluminum, and a substrate made of other metal or a ceramic substrate may be used.

The substrate 10 is fixed to the base substrate 15 by the vibration insulating members 8 at four locations. Note that the number of vibration insulating members 8 is not limited to four and may be three or five or more.

As shown in FIG. 3, the vibration insulating members 8 employ a vibration insulating structure formed by elastic bodies 3a, 3b, a collar 4, a washer 5, a bolt 6, and the like and sandwiching the substrate 10 with the elastic bodies 3a, 3b.

In a preferred example, a gel bushing is used as the elastic bodies 3a, 3b. Note that they are not limited to a gel bushing and may be any elastic member. For example, they may be silicone rubber, other type of rubber, or elastomer.

The elastic body 3a includes a semispherical portion and a tubular portion extending upward from the semispherical portion, and the tubular portion is inserted into a hole 11 in the substrate 10. A through-hole through which to insert the collar 4 is formed in the tubular portion and the semispherical portion.

The collar 4 is a tubular collar and is made of, in a preferred example, brass. Note that the collar 4 is not limited to being made of brass and may be made of, for example, aluminum, other type of metal, or resin.

The elastic body 3b is a semispherical member pairing with the elastic body 3a and is provided with a hole at the center. The tubular portion of the elastic body 3a is inserted through the hole in the elastic body 3b. The pair of elastic bodies 3a, 3b is also referred to as an elastic body 3.

As the washer 5, a washer made of aluminum is used in a preferred example. Note that the washer 5 is not limited to being made of aluminum and may be made of other metal or resin.

As the bolt 6, a bolt made of stainless steel is used in a preferred example. Note that the bolt 6 is not limited to being made of stainless steel and may be made of any metal such as, for example, steel or other metal.

As shown in FIG. 3, the tubular portion of the elastic body 3a is inserted through the hole 11 in the substrate 10, and the elastic body 3b fits around the tubular portion protruding upward from the hole 11. Then, with the collar 4 set in the through-hole in the tubular portion of the elastic body 3a, the bolt 6 is inserted with the washer 5 interposed in between, and a thread at the tip of the bolt 6 is screwed into the base substrate 15. The vibration insulating member 8 is thus configured. Being of a type where the bolt 6 is inserted, the vibration insulating member 8 can minimize lateral swinging.

Here, the collar 4 is a compression restricting member, and the bolt 6 is a fixing member. The vibration insulating member 8 is a structure such that the elastic bodies 3a, 3b are compressed with the washer 5 and the bolt 6, while the collar 4 restricts the compression so that the elastic bodies 3a, 3b may be compressed with a proper compressing pressure.

### ***Creating a Vibration Model of the Vibration Insulating Structure***

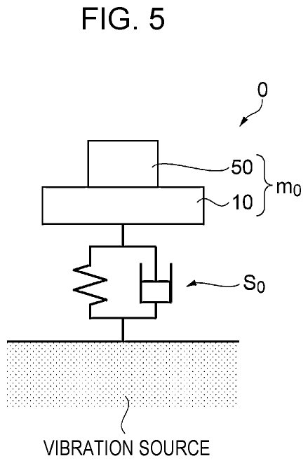

FIG. 4 is a schematic diagram of a modelled vibration insulating structure. FIG. 5 is a diagram of a vibration model used in designing a vibration insulating structure.

As shown in FIG. 4, the vibration insulating members 8 can each be expressed as a vibration model in which a spring stiffness portion k and a damping portion C in the vibration model are connected in parallel. The damping portion C is a damper and is also referred to as a damping coefficient C. The other three vibration insulating members 8 are expressed with the same vibration model. Note that in FIG. 4, the base substrate 15 is regarded as being integral with a vibration source.

Computation in the method for designing the vibration insulating structure to be described later is performed using a vibration model 0 in FIG. 5, which is an aggregation of the four vibration insulating members in the model in FIG. 4 into one.

### ***Obtaining Unit Parameter***

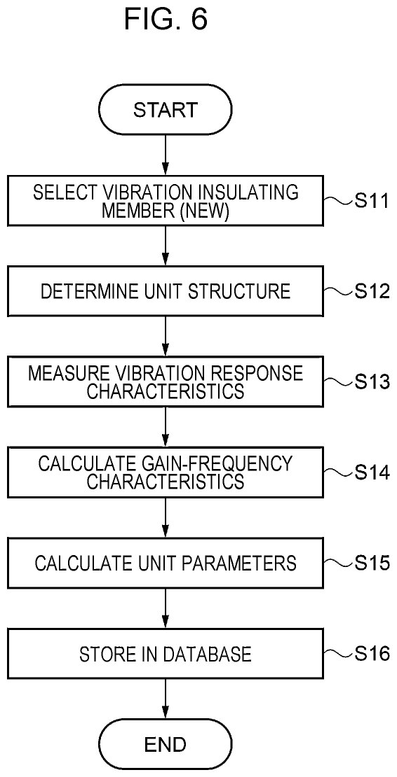

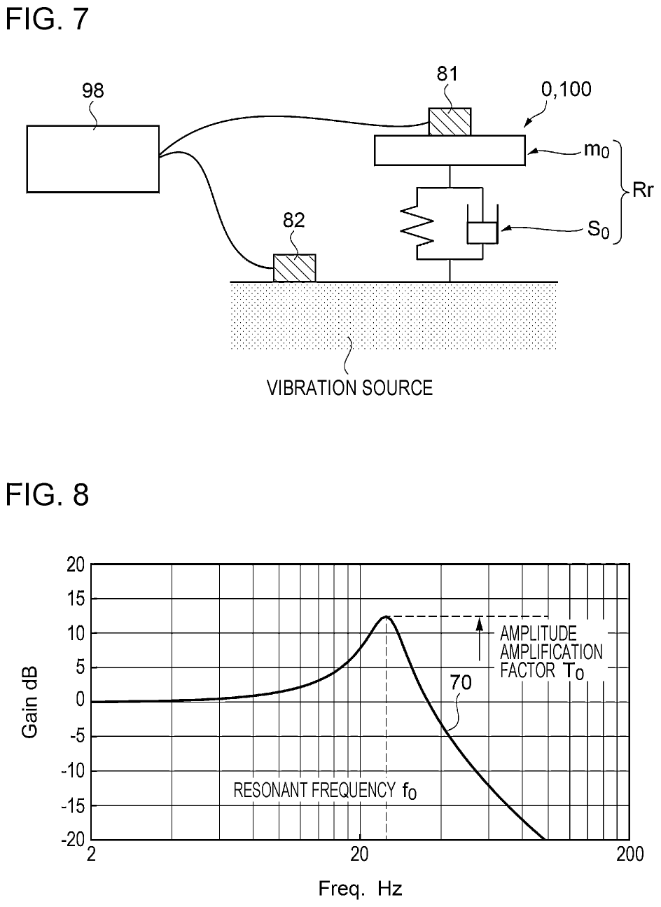

FIG. 6 is a flowchart showing how unit parameters are obtained. FIG. 7 is an overview diagram of a unit-parameter measurement apparatus.

First, a description is given of how to obtain unit parameters for a vibration insulating structure, which is a preparatory operation performed in designing the vibration insulating structure.

In Step S11, a vibration insulating member is selected. Specifically, a vibration insulating member that can be used in the vibration insulating structure to be designed is selected, and unit parameters are obtained individually for the vibration insulating member selected. The vibration insulating member may be a commercially available general-purpose component or may be a vibration insulating member designed for the specific purpose.

In Step S12, a vibration insulating structure on which to perform measurement for obtaining its unit parameters is determined. In a preferred example, the vibration insulating structure 100 in FIG. 2 is employed, and the vibration insulating structure determined is regarded as a unit structure of the vibration model 0 in FIG. 5. Note that the vibration model 0 is also referred to as a 0-th vibration insulating structure.

In Step S13, the selected vibration insulating member is attached to the vibration insulating structure 100, and vibration response characteristics are measured using a measurement apparatus 98 in FIG. 7. Specifically, as shown in FIG. 7, the measurement apparatus 98 has two sensors 81, 82, the sensor 82 being attached to a vibration source, the sensor 81 being attached to an upper part of the vibration insulating structure 100. In a preferred example, the vibration source is a vibration table such as a vibration exciter, and the sensors 81, 82 are acceleration sensors. The measurement apparatus 98 measures outputs from the two sensors 81, 82 while giving a frequency sweep of the vibration acceleration of the vibration source.

In Step S14, vibration propagation frequency characteristics G_{AB}(f) are found using Mathematical Formula (1). Specifically, based on the frequency characteristics of vibration responses obtained by performing FFT processing on the vibration responses obtained, the vibration propagation frequency characteristics G_{AB}(f) are found by dividing frequency characteristics Ga(f) of the vibration response of the sensor 81 by frequency characteristics Gb(f) of the vibration response of the sensor 82.

$${G}_{AB} ( f ) = \frac{{G}_{a} ( f )}{{G}_{b} ( f )} \qquad Formula ( 1 )$$

FIG. 8 is a graph showing an example of gain-frequency characteristics, the horizontal axis representing frequency (Hz) and the vertical axis representing gain (db). A graph 70 in FIG. 8 is an example graph showing the gain-frequency characteristics of vibration propagation found in Step S14 and shows the gain-frequency characteristics of the vibration model 0 using the selected vibration insulating member.

The graph 70 has its peak in an area after the frequency exceeds 20 Hz. As the dotted lines indicate, the frequency at the peak value is a resonant frequency f₀, and the peak value is an amplitude amplification factor T₀.

In Step S15, the resonant frequency and the amplitude amplification factor in the measured gain-frequency characteristics are calculated, and as unit parameters, a mass m₀ of a mass body, a vibration insulating member S₀, the resonant frequency f₀, and the amplitude amplification factor T₀ are set as a set of parameters.

In other words, in a 0-th vibration insulating structure including a vibration insulating member connected to a vibration source and a mass body supported by the vibration insulating member, the unit parameter is a combination of data including a resonant frequency calculated from gain-frequency characteristics of the 0-th vibration insulating structure, an amplitude amplification factor of the resonant frequency, a quantity of the vibration insulating member, and a quantity of the mass body.

In Step S16, the set of unit parameters obtained are stored in a database as unit parameter data on one of various vibration insulating members.

In other words, regarding a 0-th vibration insulating structure including a vibration insulating member connected to a vibration source and a mass body supported by the vibration insulating member, a method for generating the database of the unit parameter includes: measuring gain-frequency characteristics of the 0-th vibration insulating structure; based on a result of the measuring, calculating a resonant frequency and an amplitude amplification factor; generating a unit parameter as a combination of the resonant frequency and the amplitude amplification factor obtained by the calculating, a quantity of the vibration insulating member, and a quantity of the mass body; and storing the generated unit parameter in the database.

### ***Method for Designing a Single-Layer Vibration-Insulating Structure***

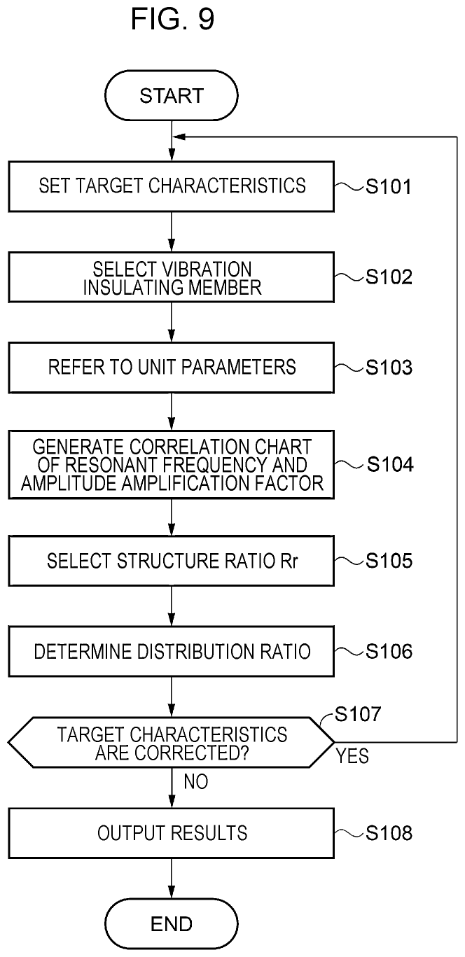

FIG. 9 is a flowchart showing how a vibration insulating structure is designed.

A description is given here of a method for designing a single-layer vibration insulating structure including a single substrate 10 shown in FIG. 2. Note that a method for designing a vibration insulating structure is also referred to as a method for manufacturing a vibration insulating structure.

In Step S101, vibration insulating characteristics to design are defined. The vibration insulating characteristics include a permissible maximum amplitude amplification factor, a permissible minimum resonant frequency, a desired damping rate increasing frequency, and a minimum quantity of the vibration insulating member used.

In Step S102, a vibration insulating member to use is selected. The vibration insulating member is selected from ones for which unit parameters have already been obtained, but in a case of using a vibration insulating member not registered in the database, unit parameters are obtained and added to the database first.

In Step S103, the database is searched to refer to unit parameters corresponding to the vibration insulating member to use. Regarding the vibration model 0 in FIG. 7, the mass m₀ of a mass body, the vibration insulating member S₀, the resonant frequency f₀, and the amplitude amplification factor T₀ are referred to. Then, the ratio of the resonant frequency f₀ and the amplitude amplification factor T₀ is set as a structure ratio Rref=1.

In Step S104, based on the unit parameters referred to, a correlation chart of the resonant frequency and the amplitude amplification factor is generated.

First, regarding the vibration model 0 in FIG. 7, when a mass as a unit is the mass m₀ and a given mass is a mass m, a ratio mr of the mass to the mass as a unit is mr=m/m₀.

Also, when a vibration insulating member as a unit is the vibration insulating member S₀ and a given vibration insulating member is a vibration insulating member S, a ratio Sr of the vibration insulating member to the vibration insulating member as a unit is Sr=S/S₀.

Then, a structure ratio Rr is defined based on the mass ratio mr and the vibration insulating member ratio Sr. The structure ratio Rr is expressed by Mathematical Formula (2).

$${R}_{r} = \frac{{S}_{r}}{{m}_{r}} = \frac{S}{{S}_{0}} \frac{{m}_{0}}{m} \qquad Formula ( 2 )$$

As described above, the structure ratio Rr for the single-layer vibration model 0 is a ratio obtained by dividing the vibration insulating member ratio Sr by the mass ratio mr. Note that the definition of the structure ratio is the same for a vibration model of a double-layer structure to be described later and an n-layer vibration model where n is two or more.

In other words, an n-th vibration insulating structure including the first vibration insulating structure and/or the second vibration insulating structure includes an n-th mass body and an n-th vibration insulating member, and an n-th structure ratio of the n-th vibration insulating structure is a mass ratio obtained by dividing a mass of the n-th mass body by a mass of a mass body of a unit parameter as a reference, a vibration insulating member ratio obtained by dividing a quantity of the n-th vibration insulating member by a vibration insulating member of the unit parameter as a reference, and a ratio obtained by dividing the vibration insulating member ratio by the mass ratio. Also, the n-th mass body is a member having a larger modulus of elasticity than the elastic body, and a quantity of the n-th mass body is a weight. Note that in a preferred example, the member having a larger modulus of elasticity is a substrate.

Based on the unit parameters referred to, the structure ratio Rr of the mass m₀ and the vibration insulating member S₀ is the structure ratio Rref of the vibration insulating structure as a unit. The structure ratio Rref is expressed by Mathematical Formula (3).

$${R}_{r} = {R}_{ref} = \frac{{S}_{0}}{{m}_{0}} \frac{{m}_{0}}{{S}_{0}} = 1 \qquad Formula ( 3 )$$

When the resonant frequency in the structure ratio Rref is a resonant frequency f₀(Rref) and the amplitude amplification factor in the structure ratio Rref is an amplitude amplification factor T₀(Rref), an amplitude amplification factor Test (Rr) of a given structure ratio Rr is calculated based on Mathematical Formula (4), which is an approximate expression.

$${T}_{est} ( {R}_{r} ) = \frac{{T}_{0} ( {R}_{ref} )}{\sqrt{{R}_{r}}} \qquad Formula ( 4 )$$

Then, a resonant frequency fest (Rr) of the given structure ratio Rr is calculated based on Mathematical Formula (5), which is an approximate expression.

$${f}_{est} ( {R}_{r} ) = {f}_{0} ( {R}_{ref} ) \sqrt{{R}_{r}} \sqrt{1 - {( \frac{1}{2 {T}_{est} ( {R}_{r} )} )}^{2}} \qquad Formula ( 5 )$$

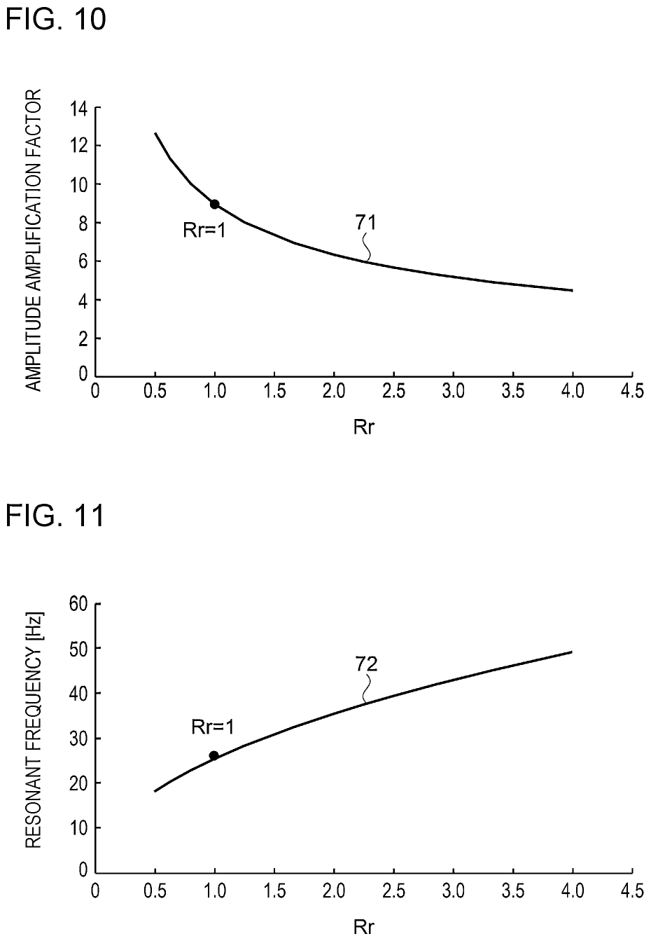

FIG. 10 is a graph showing an example correlation between a given structure ratio Rr and an amplitude amplification factor, in which the horizontal axis represents the structure ratio (Rr) and the vertical axis represents the amplitude amplification factor. FIG. 11 is a graph showing an example correlation between a given structure ratio Rr and a resonant frequency, in which the horizontal axis represents the structure ratio (Rr) and the vertical axis represents the resonant frequency (Hz).

A graph 71 in FIG. 10 shows that the larger the structure ratio Rr, the smaller the amplitude amplification factor. On the other hand, a graph 72 in FIG. 11 shows that the larger the structure ratio Rr, the higher the resonant frequency.

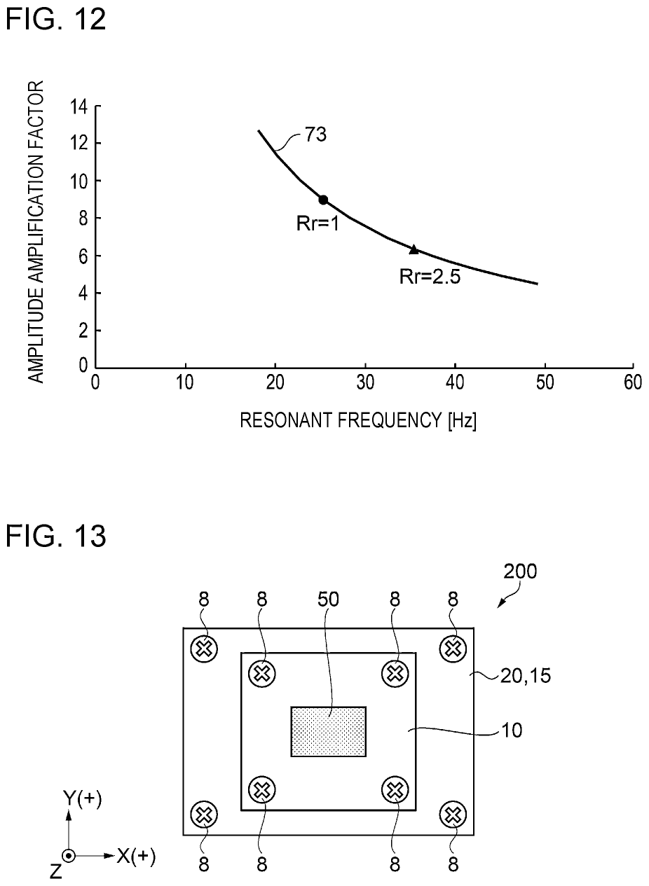

FIG. 12 is a graph showing an example correlation between a resonant frequency and an amplitude amplification factor using the structure ratio Rr a parameter, in which the horizontal axis represents the resonant frequency (Hz) and the vertical axis represents the amplitude amplification factor.

A graph 73 in FIG. 12 shows, as an example, a point where the structure ratio Rr=1 and a point where the structure ratio Rr=2.5. From this graph 73, the structure ratio Rr for obtaining the resonant frequency and the amplitude amplification factor close to conditions for the desired vibration insulating characteristics can be selected. Note that the graph 73 is referred to as a correlation chart of a resonant frequency and an amplitude amplification factor.

In Step S105, a point with the resonant frequency and the amplitude amplification factor close to conditions for the desired vibration insulating characteristics is selected on the generated correlation chart between the resonant frequency and the amplitude amplification factor.

In Step S106, the mass and the vibration insulating member are determined based on a given structure ratio Rrs corresponding to the selected point. Specifically, a mass km₀ and a vibration insulating member jS₀ are found based on the given structure ratio Rrs using Mathematical Formula (6), and a given allocation ratio of the mass and the vibration insulating member is determined:

$${R}_{rs} = {nR}_{ref} = \frac{{jS}_{0}}{{S}_{0}} \times \frac{{m}_{0}}{{km}_{0}} \qquad Formula ( 6 )$$

where n=j/k, n≥j≥1, and 1/n≤k≤1.

In a preferred example, the quantity of the vibration insulating member is the number of vibration insulating members. For example, when the structure ratio Rr=2.5 on the graph 73, its multiplying factor n with respect to the reference structure ratio is 2.5, and this 2.5 is distributed between j and k. When j is 1, k is 1/2.5.

This means that the vibration insulating member can be configured with a mass which is 1/2.5 of the mass of the vibration insulating structure measured with the unit parameters, and the number of vibration insulating members is four. Note that the quantity of vibration insulating member is not limited to the number of pieces and may be, for example, the volume of the elastic body of the vibration insulating member or the area of contact between the elastic body and the substrate.

In other words, the quantity of the n-th vibration insulating member is a number of the vibration insulating members, a volume of an elastic body of the vibration insulating member, or an area of contact between the elastic body and the n-th mass body.

In Step S107, it is determined whether the calculated mass and vibration insulating member are appropriate, and if optimization is necessary, processing proceeds back to Step S101 to perform calculation again.

In Step S108, the results derived in Step S106 are outputted.

As thus described, the vibration insulating structure of the present embodiment and the method for manufacturing the vibration insulating structure can offer the following advantageous effects.

In a conventional practice, a vibration insulating structure is designed through trial and error by selecting a vibration insulating member that seems to work, incorporating the vibration insulating member into a vibration insulating structure, and repeating an evaluation test individually. Because vibration characteristic parameters of commercially available vibration insulating members are not disclosed and therefore cannot be readily obtained, repeating prototyping and experimentation is the only way to design a vibration insulating structure. This requires a long time for designing and is also costly. Also, vibration insulation in an inertial measurement unit operates in a different frequency range from general vibration insulation; therefore, there has been no method for optimizing a vibration insulating structure with damping characteristics suitable for an inertial measurement unit (the resonance amplification factor does not increase).

In this regard, according to the method for manufacturing a vibration insulating structure of the present embodiment, a database of unit parameters is generated beforehand about a plurality of selectable vibration insulating members. The unit parameters in the database are used to generate a correlation chart of a resonant frequency and an amplitude amplification factor using a structure ratio used as a parameter, and by referring to the correlation chart, a structure ratio for obtaining the resonant frequency and the amplitude amplification close to conditions for the desired vibration characteristics can be selected.

Thus, a vibration insulating structure with desired damping characteristics (the amplitude amplification factor does not increase and the damping rate is large) can be designed in a short period of time, and cost reduction is also achieved.

Thus, a vibration insulating structure having desired vibration insulation characteristics and a method for manufacturing the same can be provided.

### Embodiment 2

### ***Double-Layer Vibration Insulating Structure***

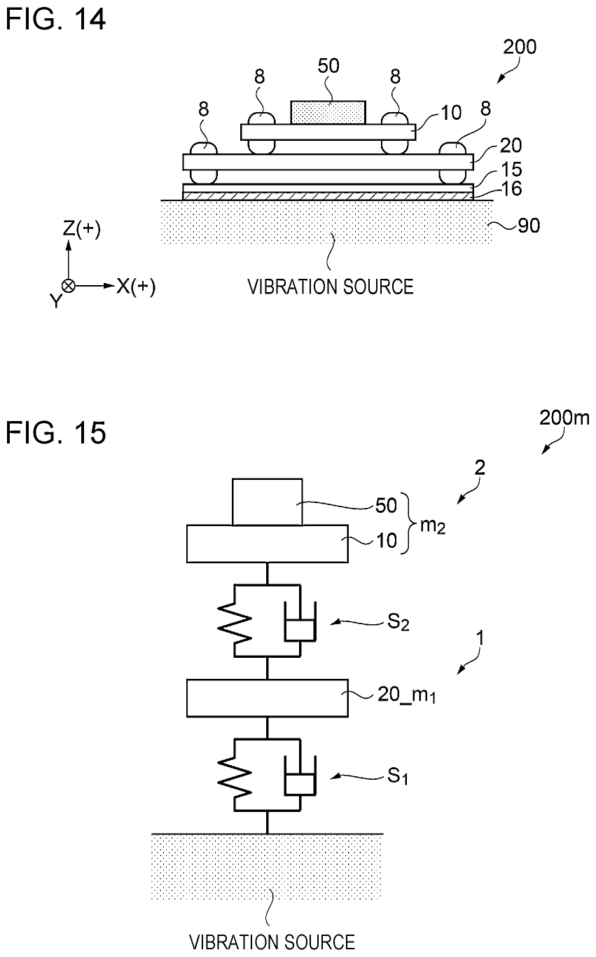

FIG. 13 is a plan view of a vibration insulating structure according to Embodiment 2 and corresponds to FIG. 1. FIG. 14 is a side view of the vibration insulating structure and corresponds to FIG. 2.

Although the vibration insulating structure 100 of the embodiment described above is a single-layer vibration insulating structure in which the measurement apparatus 50 is placed on the substrate 10 having the vibration insulating members 8, the present disclosure is not limited to this and may be a double-layer vibration insulating structure. Hereinbelow, a part which is the same as that in the embodiment described above is denoted by the same reference numeral to omit a repetitive description.

As shown in FIGS. 13 and 14, a vibration insulating structure 200 of the present embodiment further includes a substrate 20 between the base substrate 15 and the substrate 10. The size of the substrate 20 in a plan view is substantially the same as the base substrate 15 and is provided with the vibration insulating members 8 at its four corners. The bolts 6 (FIG. 3) of the vibration insulating members 8 at the four locations are screwed into the base substrate 15. The substrate 20 is fixed to the base substrate 15 via the four vibration insulating members 8. The substrate 20 is formed of the same material as that for the substrate 10.

As shown in FIG. 14, the bolts 6 (FIG. 3) of the vibration insulating members 8 at the four locations on the substrate 10 are screwed into the substrate 20. The substrate 10 is fixed to the substrate 20 via the four vibration insulating members 8 with the measurement apparatus 50 placed thereon. The vibration insulating structure 200 is thus a double-layer vibration insulating structure in which the substrate 20 and the substrate 10 are provided on top of each other. Note that the number of vibration insulating members 8 for each layer is not limited to four and may be three or five or more.

### ***Creating a Vibration Model of a Double-Layer Vibration Insulating Structure***

FIG. 15 is a diagram of the vibration model used in designing a double-layer vibration insulating structure and corresponds to FIG. 5.

As shown in FIG. 15, a vibration model of the double-layer vibration insulating structure 200 is a vibration model 200m having a stack of a vibration model 1 and a vibration model 2. Parameters of the vibration model 1 are a mass m₁ and a vibration insulating member S₁. Parameters of the vibration model 2 are a mass m₂ and a vibration insulating member S₂. Note that the vibration model 1 is also referred to as a vibration insulating structure 1, and the vibration model 2 is also referred to as a vibration insulating structure 2.

In other words, the vibration insulating structure 200 fixed to a vibration source and having the measurement apparatus 50 placed thereon includes the vibration insulating structure 1 as a first vibration insulating structure fixed to the vibration source and the vibration insulating structure 2 as a second vibration insulating structure provided on top of the first vibration insulating structure. The vibration insulating structure 1 includes the mass m₁ as a first mass body and the vibration insulating member S₁ as a first vibration insulating member, and the vibration insulating structure 2 includes the mass m₂ as a second mass body and the vibration insulating member S₂ as a second vibration insulating member. The measurement apparatus 50 is placed on the second mass body.

### ***Method for Designing a Double-Layer Vibration Insulating Structure***

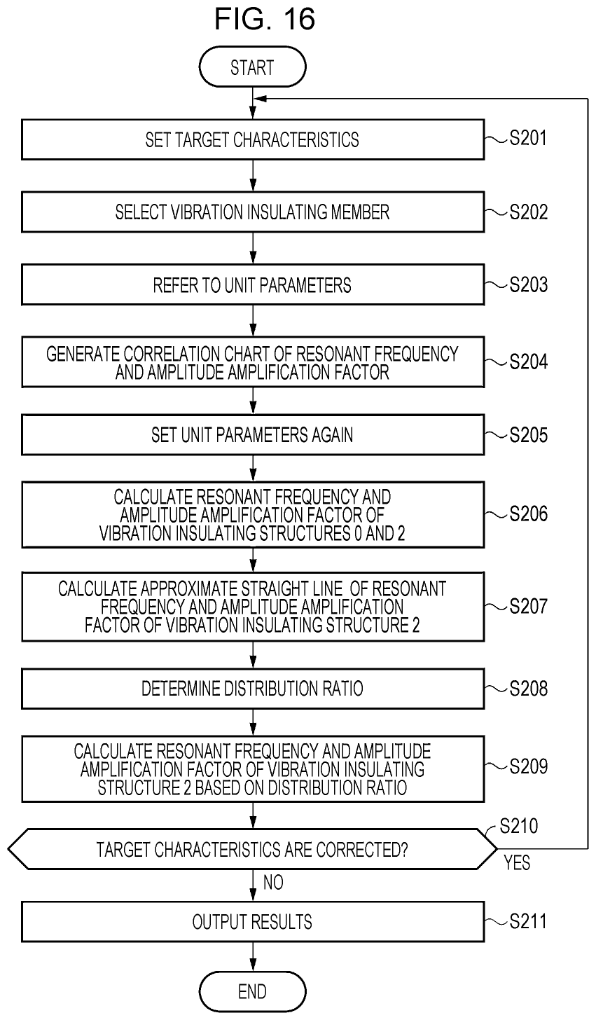

FIG. 16 is a flowchart showing how a double-layer vibration insulating structure is designed and corresponds to FIG. 9. A method for designing a double-layer vibration insulating structure is described here with reference to the vibration model 200m in FIG. 15. Note that a method for designing a vibration insulating structure is also referred to as a method for manufacturing a vibration insulating structure.

First, Steps S201 to S203 are the same as Steps S101 to S103 in FIG. 9. Specifically, vibration insulating characteristics to design are defined in Step S201, a vibration insulating member to use is selected in Step S202, and a database is searched to refer to unit parameters corresponding to the vibration insulating member to use in Step S203.

In Step S204, a correlation chart of an amplitude amplification factor and a resonant frequency with respect to the structure ratio Rr varied arbitrarily is generated for the vibration insulating structure 0 in FIG. 5. An amplitude amplification factor Test₀(Rr) for the given structure ratio Rr is calculated based on Formula (7), which is an approximate expression.

$${T}_{est 0} ( {R}_{r} ) = \frac{{T}_{0}}{\sqrt{{R}_{r}}} \qquad Formula ( 7 )$$

In addition, a resonant frequency fest₀(Rr₀) of a given structure ratio Rr₀ is calculated based on Formula (8), which is an approximate expression.

$${f}_{est 0} ( {R}_{r} ) = {f}_{0} \sqrt{{R}_{r}} \sqrt{1 − {( \frac{1}{2 {T}_{e s t} ( {R}_{r} )} )}^{2}} \qquad Formula ( 8 )$$

Next, a correlation chart of an amplitude amplification factor and a resonant frequency is generated with respect to a varying structure ratio of the vibration insulating structure 2. Note that the structure ratio Rr₀=Rr₁=Rr₂, and the vibration insulating member S₀=S₁=S₂, or the mass m₀=m₁=m₂.

When a structure ratio Rr₁=Rr₂=1, an amplitude amplification factor T₂ref is T₂ref=C_{T2}×T₀, where the coefficient C_{T2}=2. A resonant frequency f₂ref of the vibration insulating structure 2 is f₂ref=2/π f₀.

An amplitude amplification factor T₂Rr of the vibration insulating structure 2 when the given structure ratio Rr₁=Rr₂=Rr is calculated based on Formula (9), which is an approximate expression. A resonant frequency f₂(Rr) is calculated based on Formula (10), which is an approximation expression.

$${T}_{2} ( {R}_{r} ) = \frac{{T}_{2 ref}}{\sqrt{{R}_{r}}} = \frac{2 {T}_{0}}{\sqrt{{R}_{r}}} \qquad Formula ( 9 )$$

$$Formula ( 10 )$$

$${f}_{2} ( {R}_{r} ) = {f}_{2 ref} \sqrt{{R}_{r}} \sqrt{1 − {( \frac{1}{2 {T}_{2 ( {R}_{r} )}} )}^{2}} = \frac{2}{π} {f}_{0} \sqrt{{R}_{r}} \sqrt{1 − {( \frac{1}{2 {T}_{2 ( {R}_{r} )}} )}^{2}}$$

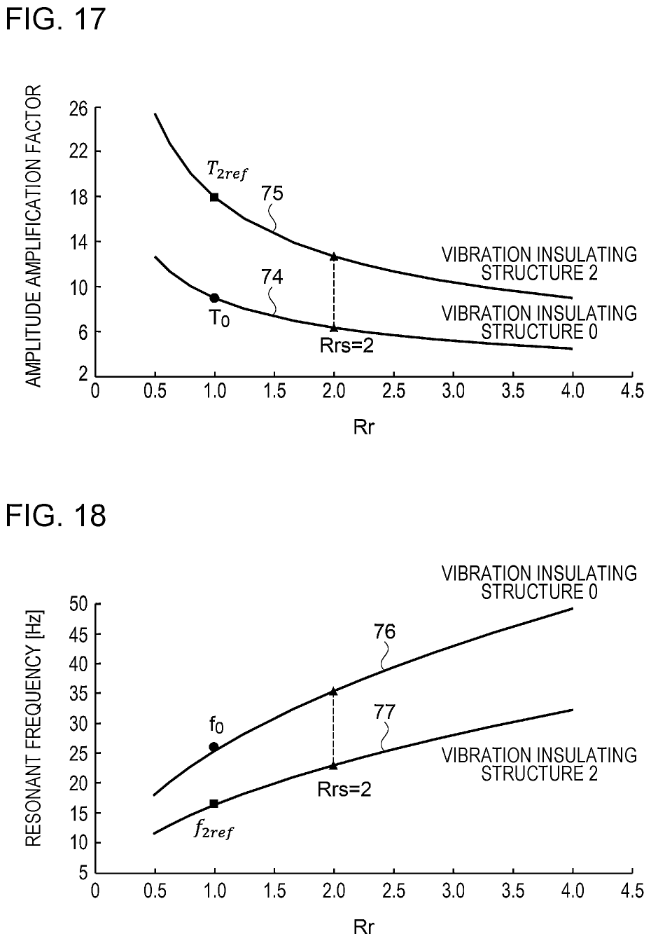

FIG. 17 is a graph showing an example correlation between a given structure ratio Rr and an amplitude amplification factor with respect to the vibration insulating structure 0 and the vibration insulating structure 2 and corresponds to FIG. 10. A graph 74 is a graph for the vibration insulating structure 0, and a graph 75 is a graph for the vibration insulating structure 2.

FIG. 18 is a graph showing an example correlation between a given structure ratio Rr and a resonant frequency with respect to the vibration insulating structure 0 and the vibration insulating structure 2 and corresponds to FIG. 11. A graph 76 is a graph for the vibration insulating structure 0, and a graph 77 is a graph for the vibration insulating structure 2.

In Step S205, the structure ratio Rrs including a desired resonant frequency fp and a desired amplitude amplification factor Tp is selected from the correlation graphs of the given structure ratio Rr and the amplitude amplification factor or the resonant frequency with respect to the vibration insulating structure 0 and the vibration insulating structure 2 generated in S204 and shown in FIGS. 17 and 18, and unit parameters for the vibration insulating structure 0 and the vibration insulating structure 1 are set again.

A structure ratio Rrs including the desired amplitude amplification factor Tp is selected on a straight line connecting the amplitude amplification factor Test₀(Rr) of the vibration insulating structure 0 and an amplitude amplification factor T₂(Rr) of the vibration insulating structure 2, using the structure ratio Rr as a parameter. Their relation is expressed by the following formula:

Test₀(Rrs)≤Tp≤T₂(Rrs).

A structure ratio Rrs including a desired resonant frequency fp is selected on a straight line connecting a resonant frequency fest₀(Rr) of the vibration insulating structure 0 and the resonant frequency f₂(Rr) of the vibration insulating structure 2 using the structure ratio Rr as a parameter. Their relation is expressed by the following formula:

f₂(Rrs)≤fp≤fest₀(Rrs).

Then, the selected structure ratio Rrs is updated as the structure ratio Rr₀ of the vibration insulating structure 0. A resonant frequency fest₀(Rrs) and an amplitude amplification factor Test₀(Rrs) of the vibration insulating structure 0 corresponding to this are set as a resonant frequency f₀s and an amplitude amplification factor T₀s, respectively, as unit parameters of the vibration insulating structure 0.

Based on the selected structure ratio Rrs, the mass km₀ and the quantity of vibration insulating member jS₀ of the vibration insulating structure 0 are defined using Mathematical Formula (11):

$${R}_{r s} = n {R}_{rref} = \frac{{jS}_{0}}{{S}_{0}} \times \frac{{m}_{0}}{k {m}_{0}} = \frac{{S}_{0 s}}{{S}_{0}} \times \frac{{m}_{0}}{{m}_{0 s}} \qquad Formula ( 11 )$$

where n=j/k, n≥j≥1, and 1/n≤k≤1.

The selected structure ratio Rrs and the allocated mass km₀ and quantity of vibration insulating member jS₀ are turned into unit parameters of the vibration insulating structure 0, the vibration insulating structure 1, and the vibration insulating structure 2, as expressed by the following formulae.

$${Rr}_{0} = {Rr}_{1} = {Rr}_{2} = 1$$

$${S}_{0} \to {S}_{∘} = {S}_{1} = {S}_{2}$$

$${m}_{0 S} \to {M}_{0} = {M}_{1} = {M}_{2}$$

In Step S206, based on the unit parameters of the vibration insulating structure 0, an amplitude amplification factor T_{0(Rr0=0.5)} and a resonant frequency f_{0(Rr0=0.5)} when the structure ratio Rr₀=0.5 are calculated using Mathematical Formulae (12) and (13), respectively.

$${T}_{0 ( {R}_{r 0} = 0.5 )} = \frac{{T}_{05}}{\sqrt{0.5}} \qquad Formula ( 12 )$$

$${f}_{0 ( {R}_{r 0} = 0.5 )} = {f}_{0 s} \sqrt{0.5} \sqrt{1 − {( \frac{1}{2 {T}_{0 ( {R}_{r 0} = 0.5 )}} )}^{2}} \qquad Formula ( 13 )$$

Next, based on the fact that the vibration insulating structure 1 and the vibration insulating structure 2 have the same unit parameters and based on the resonant frequency f₀s and the amplitude amplification factor T₀s of the vibration insulating structure 0, an amplitude amplification factor T_{2A(Rr2=1)} and a resonant frequency f_{2A(Rr2=1)} of the vibration insulating structure 2 when a structure ratio Rr₂₌₁ are calculated using the formulae below:

$${T}_{2 A ( Rr 2 = 1 )} = {C}_{T 2} \times {T}_{0 S} , and$$

$${f}_{2 A ( Rr 2 = 1 )} = 2 / π \times {f}_{0 s} .$$

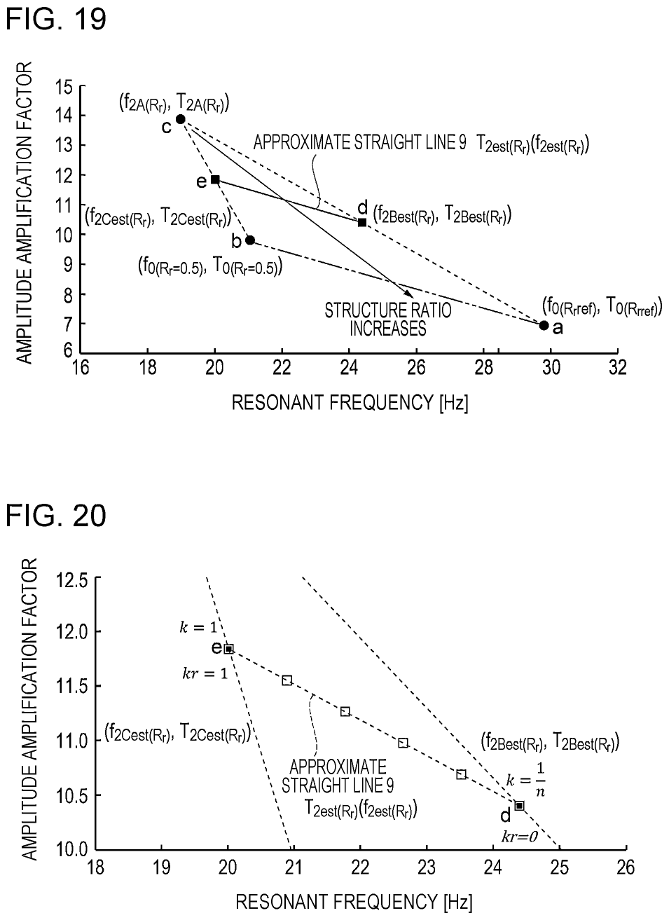

FIG. 19 is a graph showing an example correlation between a resonant frequency and an amplitude amplification factor using the structure ratio Rr of the vibration insulating structure 2 as a parameter and corresponds to FIG. 12. FIG. 20 is a graph showing a close-up of an area around an approximate straight line in FIG. 19.

Thus, as an example range in the correlation graph in FIG. 19 shows, the following three points are defined on the coordinate system of the resonant frequency and the amplitude amplification factor.
point a: (f₀s, T₀ₛ)
point b: (f_{0(Rr0=0.5)}, T_{0(Rr0=0.5)})
point c: (f_{2A(Rr2=1)}, T_{2A(Rr2=1)})

In Step S207, the structure ratio Rr of the vibration insulating structure 2 is varied within the range of n≥1 (see Mathematical Formula (14)).

$${R}_{r} = n {R}_{r 2} = \frac{{jS}_{2}}{{S}_{2}} \times \frac{{m}_{2}}{k {m}_{2}} ≧ {R}_{r 1} = 1 \qquad Formula ( 14 )$$

where n=j/k, n≥j≥1, and 1/n≤k≤1

Here, regarding the mass m₂, with a change such that j=1 and 1/n=k, approximations of an amplitude amplification factor T_{2BEST(Rr)} and a resonant frequency f_{2BEST(Rr)} of the vibration insulating structure 2 vary from point c to point b (see Mathematical Formulae (15) and (16)).

$${T}_{2 Best ( {R}_{r} )} = {T}_{0 s} − {R}_{r}^{{C}_{T 2 B}} \times ( {T}_{0 s} − {T}_{2 A ( {R}_{r 2} = 1 )} ) \qquad Formula ( 15 )$$

$${f}_{2 Bes t ( {R}_{r} )} = {f}_{0 s} − {R}_{r}^{{C}_{F 2 B}} \times ( {f}_{0 s} − {f}_{2 A ( {R}_{r 2} = 1 )} ) \qquad Formula ( 16 )$$

In the above formulae, C_{T2B}, C_{F2B} are exponents and are changes expressed by values from 1 to −0.7 using the structure ratio Rr as a parameter.

An approximation of an amplitude amplification factor T_{2est(Rr)} and a resonant frequency f_{2est(Rr)} of the vibration insulating structure 2 with a given allocation ratio at the structure ratio Rr is an approximate straight line 9 passing through point d (f_{2BEST(Rr)}, T_{2BEST(Rr)}) and point e (f2cest(Rr), T2cest(Rr)) in the correlation graph in FIG. 19. The approximate expression is Mathematical Formula (17).

$$Formula ( 17 )$$

$${T}_{2 est ( {R}_{r} )} ( {f}_{2 est ( {R}_{r} )} ) = \frac{{T}_{2 Best ( {R}_{r} )} − {f}_{2 Cest ( {R}_{r} )}}{{f}_{2 Best ( {R}_{r} )} − {f}_{2 Cest ( {R}_{r} )}} {f}_{2 est ( {R}_{r} )} + {T}_{2 Cest ( {R}_{r} )} − \frac{{T}_{2 Best ( {R}_{r} )} − {f}_{2 Cest ( {R}_{r} )}}{{f}_{2 Best ( {R}_{r} )} − {f}_{2 Cest ( {R}_{r} )}} {f}_{2 Cest ( {R}_{r} )}$$

In the above formula, the resonant frequency is in the range of f_{2Cest(Rr)}≤f_{2est(Rr)}≤f_{2BEST(Rr)}.

Here, in an imaginary triangle in FIG. 19 formed by points a and b with point c as a vertex, the second structure ratio Rr₂ of the vibration insulating structure 2 becomes larger than the first structure ratio of the vibration insulating structure 1 from point c to the bottom side connecting point a and point b, as indicated with an arrow.

In other words, the vibration insulating structure 200 includes the vibration insulating structure 1 fixed to a vibration source and the vibration insulating structure 2 provided on top of the vibration insulating structure 1, and a second structure ratio of the vibration insulating structure 2 is larger than a first structure ratio of the vibration insulating structure 1.

In Step S208, an allocation ratio of the mass m₂ and the vibration insulating member S₂ when the structure ratio Rr of the vibration insulating structure 2=n is determined using Mathematical Formula (18).

$${R}_{r} = n {R}_{r 2} = \frac{{jS}_{2}}{{S}_{2}} \times \frac{{m}_{2}}{k {m}_{2}} \qquad Formula ( 18 )$$

where n=j/k, n≥j≥1, and 1/n≤k≤1

In Step S209, a resonant frequency and an amplitude amplification factor obtained by dividing the approximate straight line 9 according to the allocation ratio are calculated. When the structure ratio Rr=n, a ratio for dividing the range of 1/n≤k≤1 is a division ratio kr. The division ratio kr is found using Mathematical Formula (19).

$${k}_{r} = \frac{nk - 1}{n - 1} \qquad Formula ( 19 )$$

The ratio for dividing the difference in frequency between point e and point d of the approximate straight line 9 is a division ratio Fr. The division ratio kr is found using Mathematical Formula (20).

$${F}_{r} = \frac{{f}_{2 Best ( {R}_{r} )} − {f}_{2 est ( n {R}_{r 2} )}}{{f}_{2 Best ( {R}_{r} )} − {f}_{2 Cest ( {R}_{r} )}} \qquad Formula ( 20 )$$

Assuming that the division ratio kr and the division ratio Fr are proportional, the relation in Mathematical Formula (21) holds true.

$${F}_{r} = {k}_{r} \frac{{f}_{2 Best ( {R}_{r} )} − {f}_{2 est ( n {R}_{r 2} )}}{{f}_{2 Best ( {R}_{r} )} − {f}_{2 Cest ( {R}_{r} )}} \qquad Formula ( 21 )$$

Then, a resonant frequency f_{2est(nRr2)} obtained by division using the division ratio kr of the mass is found using Mathematical Formula (22). An amplitude amplification factor T_{2est(nRr2)} is found using Mathematical Formula (23), which is an approximate expression.

$${f}_{2 est ( {nR}_{r 2} )} = {f}_{2 Bes t ( {R}_{r} )} - {k}_{r} ( {f}_{2 Bes t ( {R}_{r} )} - {f}_{2 Cest ( {R}_{r} )} ) \qquad Formula ( 22 )$$

$$Formula ( 23 )$$

$${T}_{2 est ( {nR}_{r 2} )} ( {f}_{2 est ( {R}_{r} )} ) = \frac{{T}_{2 Best ( {R}_{r} )} − {f}_{2 Cest ( {R}_{r} )}}{{f}_{2 Best ( {R}_{r} )} − {f}_{2 Cest ( {R}_{r} )}} {f}_{2 est ( {nR}_{r 2} )} + {T}_{2 Cest ( {R}_{r} )} − \frac{{T}_{2 Best ( {R}_{r} )} − {f}_{2 Cest ( {R}_{r} )}}{{f}_{2 Best ( {R}_{r} )} − {f}_{2 Cest ( {R}_{r} )}} {f}_{2 Cest ( {R}_{r} )}$$

The allocation ratio of the vibration insulating member S₂ is found using j=nk=kr(n −1)+1.

In Step S210, it is determined whether the mass and the vibration insulating member calculated are appropriate, and if optimization is needed, the processing proceeds back to Step S201 to perform calculation again.

In Step S211, the results derived above are outputted.

In other words, the method for manufacturing a vibration insulating structure is a method for manufacturing a vibration insulating structure having a first vibration insulating structure fixed to a vibration source and a second vibration insulating structure provided on top of the first vibration insulating structure, the first vibration insulating structure including a first mass body and a first vibration insulating member, the second vibration insulating structure including a second mass body on which a measurement apparatus is placed and a second vibration insulating member, the method including: obtaining a unit parameter for a vibration insulating member to use from a database of the unit parameter; generating a reference parameter based on a desired resonant frequency and a desired amplitude amplification factor; based on the reference parameter, defining three points on a coordinate system of a correlation between a resonant frequency and an amplitude amplification factor; based on the three points on the coordinate system, calculating an approximate straight line of a given structure ratio Rr; dividing the approximate straight line based on a division ratio and calculating a quantity of the second mass body and a quantity of the second vibration insulating member in the second vibration insulating structure; and outputting calculation results obtained by the calculating.

***Relation with the Bandwidth of the Measurement Apparatus***

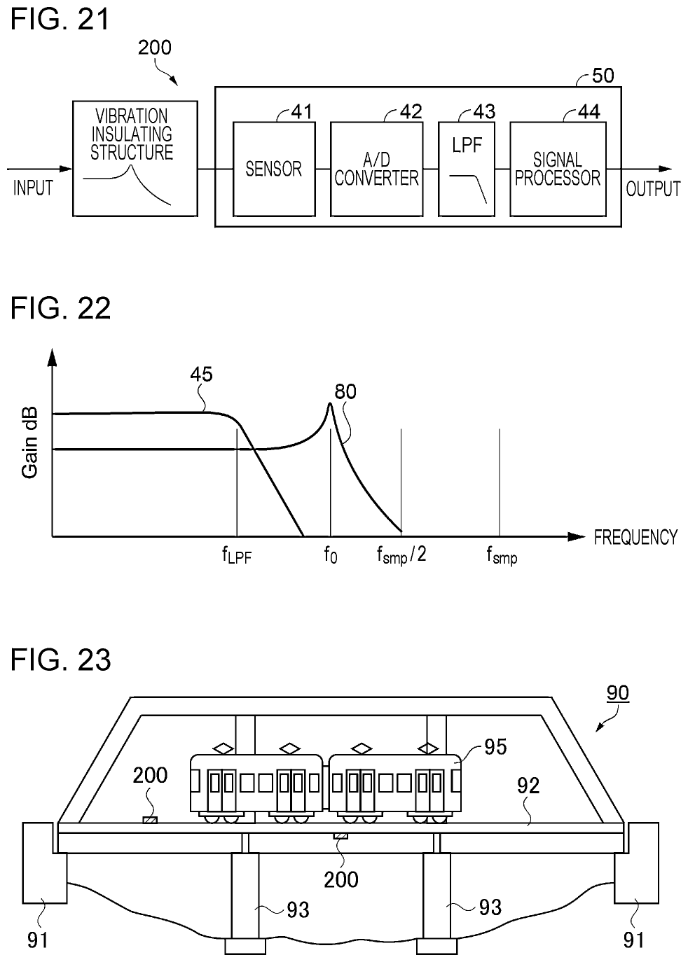

FIG. 21 is a functional block diagram of the measurement apparatus including a vibration insulating structure. FIG. 22 is a graph showing the correlation between the bandwidth of the measurement apparatus and the gain-frequency characteristics of the vibration insulating structure and corresponds to FIG. 8.

As shown in FIG. 21, the measurement apparatus 50 includes a sensor 41, an AD converter 42, an LPF 43, a signal processor 44, and the like. The sensor 41 is an inertial sensor such as an acceleration sensor or an angular velocity sensor.

As shown in FIG. 21, vibration is inputted to the sensor 41 via a vibration insulating structure having the vibration insulating members 8. A detection signal from the sensor 41 is converted from analog to digital by the AD converter 42 and is inputted to the signal processor 44 via the LPF 43, which is a low-pass filter.

In FIG. 22, a graph 80 is a graph showing the gain-frequency characteristics of the vibration insulating structure, and a graph 45 is a graph showing the cut-off frequency characteristics of the LPF 43. Note that the graph 80 shows the gain-frequency characteristics of the vibration insulating structure 2, which is the second layer of the double-layer vibration insulating structure.

As shown in FIG. 22, in the vibration insulating structure 200, in a preferred example, when the sampling frequency of the measurement apparatus 50 is a frequency fsmp, ½ of the frequency fsmp (the frequency fsmp/2) is equal to or higher than a resonant frequency fo of the vibration insulating structure 2, and also, a cut-off frequency f_{LPF} of the LPF 43 is equal to or lower than the resonant frequency fo of the vibration insulating structure 2.

The reason for making the resonant frequency fo of the vibration insulating structure 2 lower than the Nyquist frequency of the sampling frequency fsmp of the measurement apparatus 50 is to reduce the influence of aliasing in AD conversion by the AD converter 42. Also, the reason for making the cut-off frequency f_{LPF} of the LPF 43 equal to or lower than the resonant frequency fo of the vibration insulating structure 2 is to prevent the output gain of the measurement apparatus 50 from being influenced by the amplitude amplification factor.

In other words, the resonant frequency of the vibration insulating structure 200 is lower than ½ of the sampling frequency fsmp of the measurement apparatus 50 and higher than the upper limit of the output frequency band of the measurement apparatus 50.

### Example Mode of Installment of Vibration Insulating Structure

FIG. 23 is a diagram showing an example mode of installment of a vibration insulating structure.

As shown in FIG. 23, in a preferred example, the vibration insulating structure 200 having the measurement apparatus 50 placed thereon is installed at a beam 92 of a railroad bridge 90.

The bridge 90 is configured such that, for example, the beam 92 is bridged on a pair of abutments 91 provided at both banks of a river. A plurality of piers 93 are provided inward of the beam 92.

As shown in FIG. 23, the vibration insulating structure 200 is installed at each one of the upper surface and the lower surface of the beam 92. Note that a plurality of vibration insulating structures 200 may be installed at the upper surface and the lower surface. In a preferred example, the vibration insulating structure 200 is fixed to the beam 92 by having the magnet 16 (FIG. 14) pulled onto the steel frame of the beam 92. Note that the fixation is not limited to magnetic attraction; the base substrate 15 may be screwed to the beam 92 or may be attached and fixed using an adhesive.

When the vibration insulating structure 200 is thus installed at the bridge 90, the amount of warpage of the bridge 90 upon passage of a train 95 can be measured as a displacement or the like.

Note that the vibration insulating structure 200 is not limited to being installed at a bridge and may be installed at other artificial structures such as a building like an office building, a road, a tower, a utility pole, or a dam. Note that structures may include natural structures such as a mountain, a river, and a cliff. Also, the vibration insulating structure 200 is not limited to being installed at a structure, but may be installed at a mobile object such as a two-wheeled vehicle, an automobile, an agricultural vehicle such as a tractor, or a construction vehicle such as a bulldozer.

As thus described, the vibration insulating structure and the method for manufacturing the vibration insulating structure of the present embodiment can offer the following advantageous effects in addition to the ones offered by those of Embodiment 1.

A method for manufacturing a double-layer vibration insulating structure includes: obtaining a unit parameter for a vibration insulating member to use from a database of the unit parameter; generating a reference parameter based on a desired resonant frequency and a desired amplitude amplification factor; based on the reference parameter, defining three points on a coordinate system of a correlation between a resonant frequency and an amplitude amplification factor; based on the three points on the coordinate system, calculating an approximate straight line of a given structure ratio Rr; dividing the approximate straight line based on a division ratio and calculating a quantity of the second mass body and a quantity of the second vibration insulating member in the second vibration insulating structure; and outputting calculation results obtained by the calculating.

According to this, even with a double-layer vibration insulating structure, a structure ratio for obtaining a resonant frequency and an amplitude amplification factor close to conditions for desired vibration insulating characteristics can be selected. Thus, a vibration insulating structure with desired damping characteristics (the amplitude amplification factor does not increase and the damping rate is large) can be designed in a short period of time, and cost reduction can also be achieved.

Thus, a vibration insulating structure having desired vibration insulating characteristics and a method for manufacturing the same can be provided.

Also, the generating a reference parameter includes: obtaining the unit parameter for the vibration insulating member to use from the database; based on a first resonant frequency and a first amplitude amplification factor of the unit parameter, calculating a second amplitude amplification factor by multiplying the first amplitude amplification factor by a predetermined first coefficient and calculating a second resonant frequency by multiplying the first resonant frequency by 2/π; based on a structure ratio of a normalized vibration insulating member value and a normalized mass body value which are obtained by normalization of a given quantity of the vibration insulating member and a given quantity of the mass body using a quantity of the first vibration insulating member and a quantity of the first mass body of the unit parameter; calculating a correlation between the structure ratio, the first resonant frequency, the first amplitude amplification factor, the second resonant frequency, and the second amplitude amplification factor; selecting a structure ratio where the desired resonant frequency is in between the first resonant frequency and the second resonant frequency or where the desired amplitude amplification factor is in between the first amplitude amplification factor and the second amplitude amplification factor; determining the quantity of the second mass body and the quantity of the second vibration insulating member based on the quantity of the first mass body and the quantity of the first vibration insulating member of the unit parameter obtained, the selected structure ratio, and a desired distribution ratio; and setting a combination of the second resonant frequency, the second amplitude amplification factor, the quantity of the second mass body, and the quantity of the second vibration insulating member as the reference parameter for the structure ratio Rr=1.

Also, the defining three points on a coordinate system includes: based on a second resonant frequency and a second amplitude amplification factor of the reference parameter, calculating a third amplitude amplification factor from a structure ratio=0.5 and the second amplitude amplification factor; calculating a third resonant frequency from a structure ratio=0.5, the third amplitude amplification factor, and the second resonant frequency; calculating a fourth amplitude amplification factor by multiplying the second amplitude amplification factor by a predetermined first coefficient; calculating a fourth resonant frequency by multiplying the second resonant frequency by 2/π; and defining three points on a coordinate system of the second resonant frequency, the second amplitude amplification factor, the third resonant frequency, the third amplitude amplification factor, the fourth resonant frequency, and the fourth amplitude amplification factor.

Also, in the calculating an approximate straight line, a straight line passing through a point of a fifth resonant frequency and a fifth amplitude amplification factor and a point of a sixth resonant frequency and a sixth amplitude amplification factor in an orthogonal coordinate system of a resonant frequency and an amplitude amplification factor is an approximate straight line of a given structure ratio, the fifth amplitude amplification factor being obtained by subtracting, from the second amplitude amplification factor, a value obtained by multiplying a value obtained by subtracting the fourth amplitude amplification factor from the second amplitude amplification factor by a power having a first structure ratio as a base and a first exponent, the fifth resonant frequency being obtained by subtracting, from the second resonant frequency, a value obtained by multiplying a value obtained by subtracting the fourth resonant frequency from the second resonant frequency by a power having the first structure ratio as a base and a second exponent, the sixth amplitude amplification factor being obtained by subtracting, from the third amplitude amplification factor, a value obtained by multiplying a value obtained by subtracting the fourth amplitude amplification factor from the third amplitude amplification factor by a power having the first structure ratio as a base and a third exponent, and the sixth resonant frequency being obtained by subtracting, from the third resonant frequency, a value obtained by multiplying a value obtained by subtracting the fourth resonant frequency from the third resonant frequency by a power having the first structure ratio as a base and a fourth exponent.

Also, the calculating a quantity of the second mass body and a quantity of the second vibration insulating member in the second vibration insulating structure includes: on the approximate straight line of a resonant frequency range equal to or lower than the fifth resonant frequency and equal to or higher than the sixth resonant frequency, determining a division ratio for dividing the approximate straight line; calculating a seventh amplitude amplification factor and a seventh resonant frequency on the approximate straight line divided with the division ratio; calculating an allocation ratio based on the first structure ratio and the division ratio; and calculating the quantity of the second mass body and the quantity of the second vibration insulating member based on the allocation ratio and the quantity of the first vibration insulating member and the quantity of the first mass body of the reference parameter. Note that the division of the approximate straight line is not limited to division by two.

Also, the outputting calculation results includes outputting the quantity of the second vibration insulating member, the quantity of the second mass body, the seventh amplitude amplification factor, and the seventh resonant frequency.

Also, the first structure ratio is greater than 1.

Also, the first coefficient is 2.

Also, the first exponent, the second exponent, the third exponent, and the fourth exponent are values within a range from −1 to −0.7.

According to these aspects, even with a double-layer vibration insulating structure, a structure ratio for obtaining a resonant frequency and an amplitude amplification factor close to conditions for desired vibration insulating characteristics can be selected. Thus, a vibration insulating structure with desired damping characteristics (the amplitude amplification factor does not increase and the damping rate is large) can be designed in a short period of time, and cost reduction can also be achieved.

Thus, a vibration insulating structure with desired vibration insulating characteristics and a method for manufacturing the same can be provided.

What is claimed is:

1. A vibration insulating structure which is fixed to a vibration source and on which a measurement apparatus is placed, the vibration insulating structure comprising:
a first vibration insulating structure fixed to the vibration source and
a second vibration insulating structure provided on top of the first vibration insulating structure, wherein
the first vibration insulating structure includes a first mass body and a first vibration insulating member supporting the first mass body,
the second vibration insulating structure includes a second mass body and a second vibration insulating member supporting the second mass body,
the measurement apparatus is placed on the second mass body, and
a second structure ratio of the second vibration insulating structure is larger than a first structure ratio of the first vibration insulating structure.

2. The vibration insulating structure according to claim 1, wherein
an n-th vibration insulating structure including the first vibration insulating structure and/or the second vibration insulating structure includes an n-th mass body and an n-th vibration insulating member, and
an n-th structure ratio of the n-th vibration insulating structure is
a mass ratio obtained by dividing a mass of the n-th mass body by a mass of a mass body of a unit parameter as a reference,
a vibration insulating member ratio obtained by dividing a quantity of the n-th vibration insulating member by a vibration insulating member of the unit parameter as a reference, and
a ratio obtained by dividing the vibration insulating member ratio by the mass ratio.

3. The vibration insulating structure according to claim 2, wherein
the quantity of the n-th vibration insulating member is a number of the vibration insulating members, a volume of an elastic body of the vibration insulating member, or an area of contact between the elastic body and the n-th mass body.

4. The vibration insulating structure according to claim 3, wherein
the n-th mass body is a member having a larger modulus of elasticity than the elastic body, and
a quantity of the n-th mass body is a weight.

5. The vibration insulating structure according to claim 2, wherein
in a 0-th vibration insulating structure including a vibration insulating member connected to a vibration source and a mass body supported by the vibration insulating member,
the unit parameter is a combination of data including a resonant frequency calculated from gain-frequency characteristics of the 0-th vibration insulating structure, an amplitude amplification factor of the resonant frequency, a quantity of the vibration insulating member, and a quantity of the mass body.

6. The vibration insulating structure according to claim 1, wherein
a resonant frequency of the vibration insulating structure is lower than a half of a sampling frequency of the measurement apparatus and higher than an upper limit of an output frequency band of the measurement apparatus.

7. The vibration insulating structure according to claim 6, wherein
the measurement apparatus is any one of an inertial measurement unit, an inertial navigation system, an acceleration sensor, a displacement meter, a gyroscope sensor, an optical sensor, and an image measurement apparatus.

8. A method for manufacturing a vibration insulating structure having a first vibration insulating structure fixed to a vibration source and a second vibration insulating structure provided on top of the first vibration insulating structure, the first vibration insulating structure including a first mass body and a first vibration insulating member, the second vibration insulating structure including a second mass body on which a measurement apparatus is placed and a second vibration insulating member, the method comprising:
obtaining a unit parameter for a vibration insulating member to use from a database of the unit parameter;
generating a reference parameter based on a desired resonant frequency and a desired amplitude amplification factor;
based on the reference parameter, defining three points on a coordinate system of a correlation between a resonant frequency and an amplitude amplification factor;
based on the three points on the coordinate system, calculating an approximate straight line of a given structure ratio Rr;
dividing the approximate straight line based on a division ratio and calculating a quantity of the second mass body and a quantity of the second vibration insulating member in the second vibration insulating structure; and
outputting calculation results obtained by the calculating.

9. The method for manufacturing a vibration insulating structure according to claim 8, wherein
regarding a 0-th vibration insulating structure including a vibration insulating member connected to a vibration source and a mass body supported by the vibration insulating member, a method for generating the database of the unit parameter includes:
measuring gain-frequency characteristics of the 0-th vibration insulating structure,
based on a result of the measuring, calculating a resonant frequency and an amplitude amplification factor,
generating a unit parameter as a combination of the resonant frequency and the amplitude amplification factor obtained by the calculating, a quantity of the vibration insulating member, and a quantity of the mass body, and
storing the generated unit parameter in the database.

10. The method for manufacturing a vibration insulating structure according to claim 8, wherein
the generating a reference parameter includes
obtaining the unit parameter for the vibration insulating member to use from the database,
based on a first resonant frequency and a first amplitude amplification factor of the unit parameter, calculating a second amplitude amplification factor by multiplying the first amplitude amplification factor by a predetermined first coefficient and calculating a second resonant frequency by multiplying the first resonant frequency by 2/π,
based on a structure ratio of a normalized vibration insulating member value and a normalized mass body value which are obtained by normalization of a given quantity of the vibration insulating member and a given quantity of the mass body using a quantity of the first vibration insulating member and a quantity of the first mass body of the unit parameter,
calculating a correlation between the structure ratio, the first resonant frequency, the first amplitude amplification factor, the second resonant frequency, and the second amplitude amplification factor,
selecting a structure ratio where the desired resonant frequency is in between the first resonant frequency and the second resonant frequency or where the desired amplitude amplification factor is in between the first amplitude amplification factor and the second amplitude amplification factor,
determining the quantity of the second mass body and the quantity of the second vibration insulating member based on the quantity of the first mass body and the quantity of the first vibration insulating member of the unit parameter obtained, the selected structure ratio, and a desired distribution ratio, and
setting a combination of the second resonant frequency, the second amplitude amplification factor, the quantity of the second mass body, and the quantity of the second vibration insulating member as the reference parameter for the structure ratio Rr=1.

11. The method for manufacturing a vibration insulating structure according to claim 8, wherein
the defining three points on a coordinate system includes
based on a second resonant frequency and a second amplitude amplification factor of the reference parameter,
calculating a third amplitude amplification factor from a structure ratio=0.5 and the second amplitude amplification factor,
calculating a third resonant frequency from a structure ratio=0.5, the third amplitude amplification factor, and the second resonant frequency,
calculating a fourth amplitude amplification factor by multiplying the second amplitude amplification factor by a predetermined first coefficient,
calculating a fourth resonant frequency by multiplying the second resonant frequency by 2/π, and
defining three points on a coordinate system of the second resonant frequency, the second amplitude amplification factor, the third resonant frequency, the third amplitude amplification factor, the fourth resonant frequency, and the fourth amplitude amplification factor.

12. The method for manufacturing a vibration insulating structure according to claim 11, wherein
in the calculating an approximate straight line, a straight line passing through a point of a fifth resonant frequency and a fifth amplitude amplification factor and a point of a sixth resonant frequency and a sixth amplitude amplification factor in an orthogonal coordinate system of a resonant frequency and an amplitude amplification factor is an approximate straight line of a given structure ratio,
the fifth amplitude amplification factor being obtained by subtracting, from the second amplitude amplification factor, a value obtained by multiplying a value obtained by subtracting the fourth amplitude amplification factor from the second amplitude amplification factor by a power having a first structure ratio as a base and a first exponent,
the fifth resonant frequency being obtained by subtracting, from the second resonant frequency, a value obtained by multiplying a value obtained by subtracting the fourth resonant frequency from the second resonant frequency by a power having the first structure ratio as a base and a second exponent,
the sixth amplitude amplification factor being obtained by subtracting, from the third amplitude amplification factor, a value obtained by multiplying a value obtained by subtracting the fourth amplitude amplification factor from the third amplitude amplification factor by a power having the first structure ratio as a base and a third exponent, and
the sixth resonant frequency being obtained by subtracting, from the third resonant frequency, a value obtained by multiplying a value obtained by subtracting the fourth resonant frequency from the third resonant frequency by a power having the first structure ratio as a base and a fourth exponent.

13. The method for manufacturing a vibration insulating structure according to claim 12, wherein
the calculating a quantity of the second mass body and a quantity of the second vibration insulating member in the second vibration insulating structure includes:
on the approximate straight line of a resonant frequency range equal to or lower than the fifth resonant frequency and equal to or higher than the sixth resonant frequency,
determining a division ratio for dividing the approximate straight line,
calculating a seventh amplitude amplification factor and a seventh resonant frequency on the approximate straight line divided with the division ratio,
calculating an allocation ratio based on the first structure ratio and the division ratio, and
calculating the quantity of the second mass body and the quantity of the second vibration insulating member based on the allocation ratio and the quantity of the first vibration insulating member and the quantity of the first mass body of the reference parameter.

14. The method for manufacturing a vibration insulating structure according to claim 13, wherein
the outputting calculation results includes outputting the quantity of the second vibration insulating member, the quantity of the second mass body, the seventh amplitude amplification factor, and the seventh resonant frequency.

15. The method for manufacturing a vibration insulating structure according to claim 12, wherein
the first structure ratio is greater than 1.

16. The method for manufacturing a vibration insulating structure according to claim 10, wherein
the first coefficient is 2.

17. The method for manufacturing a vibration insulating structure according to claim 12, wherein
the first exponent, the second exponent, the third exponent, and the fourth exponent are values within a range from −1 to −0.7.
